(19) United States
(12) Patent Application Publication
(10) Pub. No.: US 2023/0135155 A1
(43) Pub. Date: May 4, 2023

(54) Atomic Layer Etching to Reduce Pattern Loading in High-K Dielectric Layer

(71) Applicant: Taiwan Semiconductor Manufacturing Co., Ltd., Hsinchu (TW)

(72) Inventors: Yen-Fu Chen, Taipei (TW); Kuei-Lun Lin, Keelung City (TW); Da-Yuan Lee, Jhubei City (TW); Chi On Chui, Hsinchu (TW)

(21) Appl. No.: 17/648,431

(22) Filed: Jan. 20, 2022

Related U.S. Application Data
(60) Provisional application No. 63/275,506, filed on Nov. 4, 2021.

(51) Int. Cl. H01L 21/02; H01L 29/66; H01L 21/768

(52) U.S. Cl. CPC H01L 21/0228; H01L 29/66545; H01L 21/76802; H01L 21/76829

(57) ABSTRACT

A method includes forming a first trench and a second trench in a base structure. The first trench has a first aspect ratio, and the second trench has a second aspect ratio lower than the first aspect ratio. A deposition process is then performed to deposit a layer. The layer includes a first portion extending into the first trench, and a second portion extending into the second trench. The first portion has a first thickness. The second portion has a second thickness greater than the first thickness by a first difference. The method further includes performing an etch-back process to etch the layer. After the etch-back process, the first portion has a third thickness, and the second portion has a fourth thickness. A second difference between the third thickness and the fourth thickness is smaller than the first difference.

### PRIORITY CLAIM AND CROSS-REFERENCE

This application claims the benefit of the following provisionally filed U.S. Patent application: Application No. 63/275,506, filed on Nov. 4, 2021, and entitled “Semiconductor Structure and Method for Manufacturing the Same,” which application is hereby incorporated herein by reference.

### BACKGROUND

Metal-Oxide-Semiconductor (MOS) devices are basic building elements in integrated circuits. An existing MOS device typically has a gate electrode formed of polysilicon doped with p-type or n-type impurities, using doping operations such as ion implantation or thermal diffusion. The work function of the gate electrode may be adjusted to the band-edge of silicon. For an n-type Metal-Oxide-Semiconductor (NMOS) device, the work function may be adjusted to close to the conduction band of silicon. For a P-type Metal-Oxide-Semiconductor (PMOS) device, the work function may be adjusted to close to the valence band of silicon. Adjusting the work function of the polysilicon gate electrode can be achieved by selecting appropriate impurities.

MOS devices with polysilicon gate electrodes exhibit carrier depletion effect, which is also known as a poly depletion effect. The poly depletion effect occurs when the applied electrical fields sweep away carriers from gate regions close to gate dielectrics, forming depletion layers. In an n-doped polysilicon layer, the depletion layer includes ionized non-mobile donor sites, wherein in a p-doped polysilicon layer, the depletion layer includes ionized non-mobile acceptor sites. The depletion effect results in an increase in the effective gate dielectric thickness, making it more difficult for an inversion layer to be created at the surface of the semiconductor.

The poly depletion problem may be solved by forming metal gate electrodes, wherein the metallic gates used in NMOS devices and PMOS devices may also have band-edge work functions. Accordingly, the resulting metal gates include a plurality of layers to meet the requirements of the NMOS devices and PMOS devices. The gate dielectrics of the MOS devices are also replaced.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-6, 7A, 7B, 8A, 8B, 9A, 9B, and 10-14 illustrate the cross-sectional views and perspective views of intermediate stages in the formation of Fin Field-Effect Transistors (FinFETs) in accordance with some embodiments.

FIGS. 15-18 illustrate the cross-sectional views and perspective views of intermediate stages in the formation of a layer having same thicknesses in different trenches that have different aspect ratios in accordance with some embodiments.

FIG. 19 schematically illustrates the thickness difference during a deposition process and an etch-back process in accordance with some embodiments.

FIG. 20 illustrates a process flow for forming FinFETs in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Fin Field-Effect Transistors (FinFETs) and the methods of forming the same are provided in accordance with some embodiments. High-k dielectric layers of a long-channel FinFET and a short-channel FinFET are deposited in a same deposition process, which may be an Atomic Layer Deposition (ALD) process. Due to the difference in the channel lengths and hence different aspect ratio values, the high-k dielectric layers of the long-channel FinFET and the short-channel FinFET have difference thicknesses. An atomic Layer Etching (ALE) process is then performed, and process conditions are controlled to etch back the high-k dielectric layers, and to reduce the difference in their thicknesses. It is appreciated that although FinFETs are used in example embodiments, the concept of the present disclosure may also be applied on other types of transistors such as Gate-All-Around (GAA) transistors and planar transistors. Also, the method may also be used for achieving uniform deposition into trenches. The intermediate stages of forming the transistors are illustrated in accordance with some embodiments. Some variations of some embodiments are discussed. Throughout the various views and illustrative embodiments, like reference numbers are used to designate like elements.

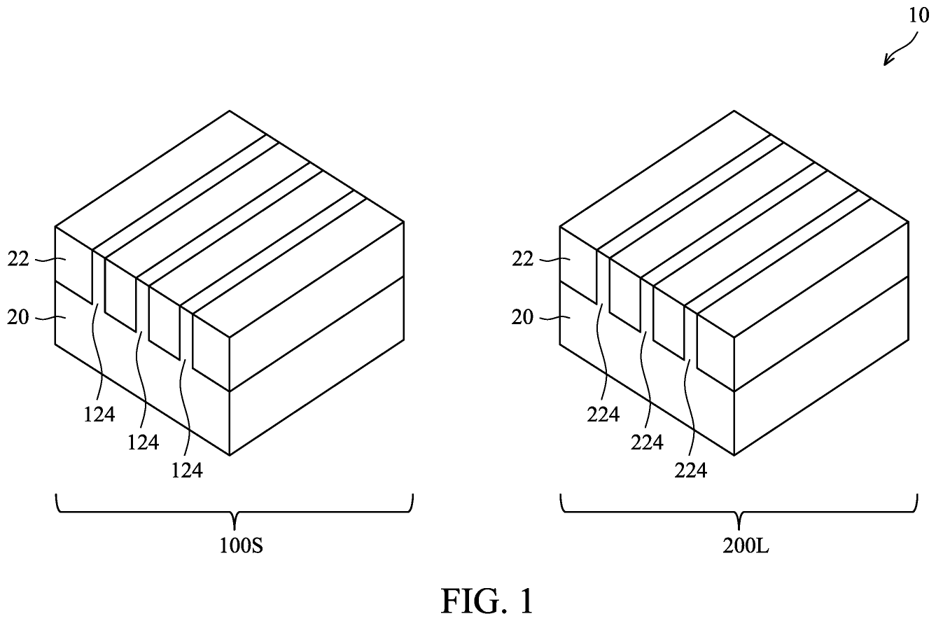

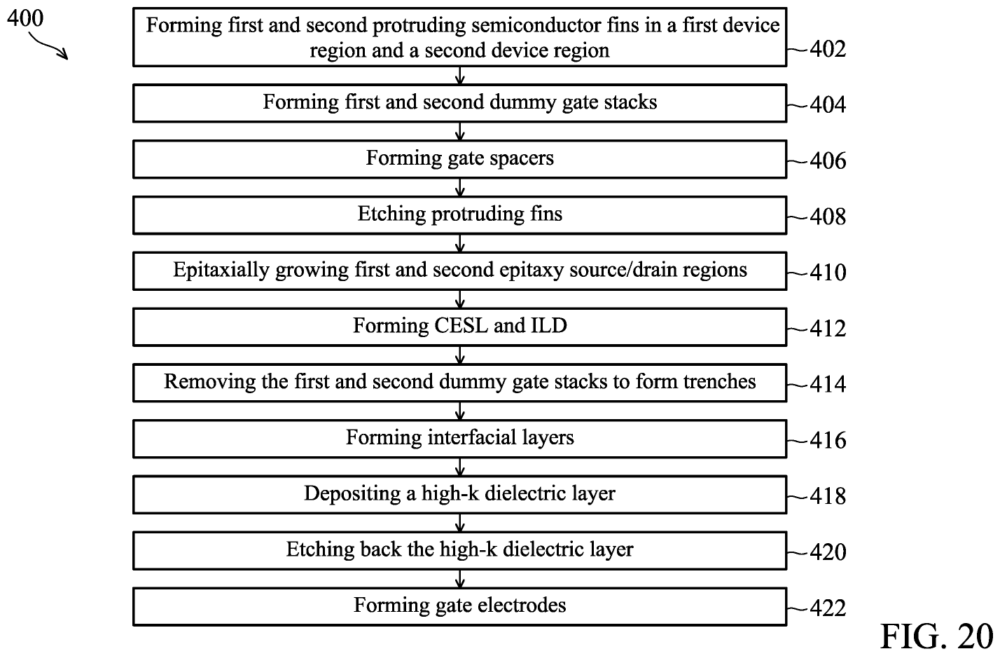

FIGS. 1-6, 7A, 7B, 8A, 8B, 9A, 9B, and 10-14 illustrate the cross-sectional views and perspective views of intermediate stages in the formation of FinFETs in accordance with some embodiments of the present disclosure. The processes are also reflected schematically in the process flow 400 shown in FIG. 20.

FIG. 1 illustrates a perspective view of an initial structure. The initial structure includes wafer 10, which further includes substrate 20. Substrate 20 may be a semiconductor substrate, which may be a silicon substrate, a silicon germanium substrate, or a substrate formed of other semiconductor materials. In accordance with some embodiments, substrate 20 is a bulk silicon substrate. In accordance with alternative embodiments, substrate 20 includes a bulk silicon substrate and an epitaxy silicon germanium (SiGe) layer or a germanium layer (without silicon therein) over the bulk silicon substrate. Substrate 20 may be doped with a p-type or an n-type impurity.

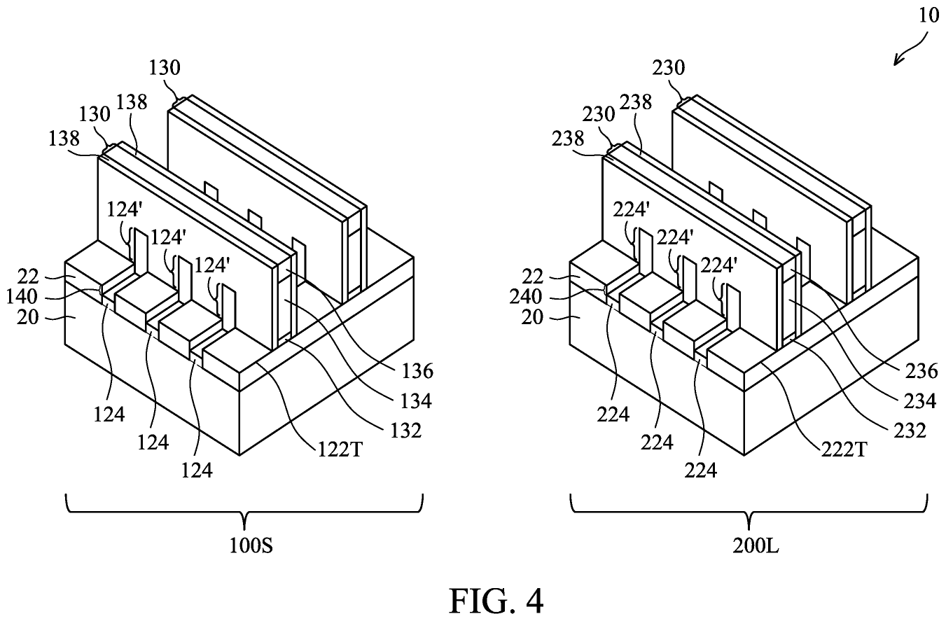

Substrate 20 includes portions in device regions 100S and 200L, in which a first FinFET and a second FinFET are to be formed. In accordance with some embodiments, a short-channel FinFET is to be formed in device region 100S, and a long-channel FinFET is to be formed in device region 200L. The short-channel FinFET has a channel shorter than the channel of the long-channel FinFET. To distinguish the features in the short-channel FinFET from the features in the long-channel FinFET, some of the features in the short-channel FinFET may be prefixed with number “1,” and some the features in the long-channel FinFET may be prefixed with number “2.” For example, the source/drain regions in device regions 100S and device regions 200L are denoted as 142 and 242 (FIG. 4), respectively. The corresponding features in the short-channel FinFET and the long-channel FinFET may be formed in common processes, or may be formed in separate processes.

Isolation regions 22 such as Shallow Trench Isolation (STI) regions may be formed to extend into substrate 20. The portions of substrate 20 between neighboring STI regions 22 are referred to as semiconductor strips 124 and 224, which are in device regions 100S and 200L, respectively. STI regions 22 may include a liner oxide (not shown). The liner oxide may be formed of a thermal oxide formed through a thermal oxidation of a surface layer of substrate 20. The liner oxide may also be a deposited silicon oxide layer formed using, for example, Atomic Layer Deposition (ALD), High-Density Plasma Chemical Vapor Deposition (HDPCVD), Chemical Vapor Deposition (CVD), or the like. STI regions 22 may also include a dielectric material over the liner oxide, wherein the dielectric material may be formed using Flowable Chemical Vapor Deposition (FCVD), spin-on coating, or the like.

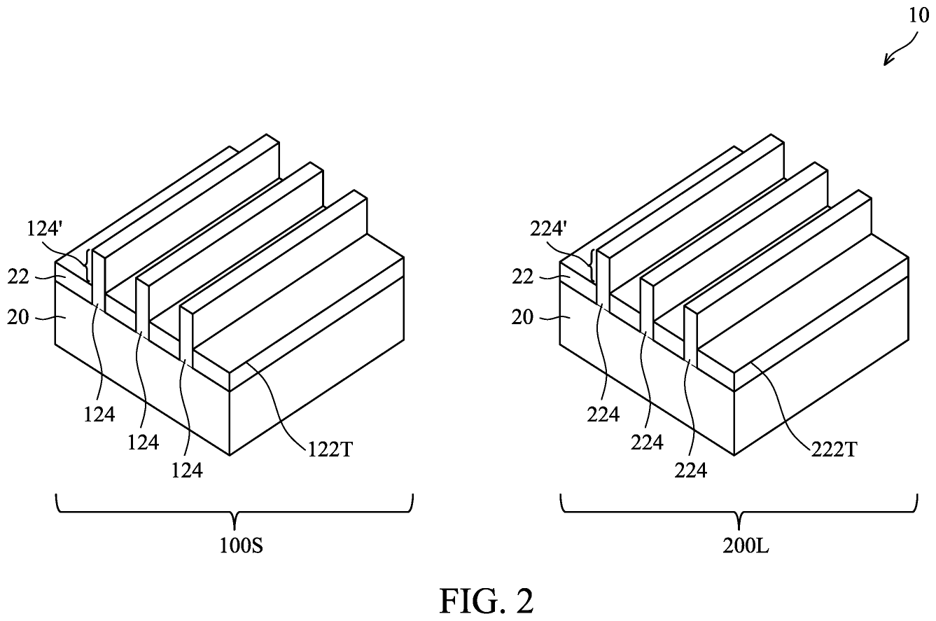

Referring to FIG. 2, STI regions 22 are recessed, so that the top portions of semiconductor strips 124 and 224 protrude higher than the top surfaces 122T and 222T of the neighboring STI regions 22 to form protruding fins 124′ and 224′, respectively. The respective process is illustrated as process 402 in the process flow 400 as shown in FIG. 20. The etching may be performed using a dry etching process, wherein the mixture of NH₃ and NF₃ or the mixture of NH₃ and HF are used as the etching gases. During the etching process, plasma may be generated. Argon may also be included. In accordance with alternative embodiments of the present disclosure, the recessing of STI regions 22 is performed using a wet etch process. The etching chemical may include diluted HF, for example.

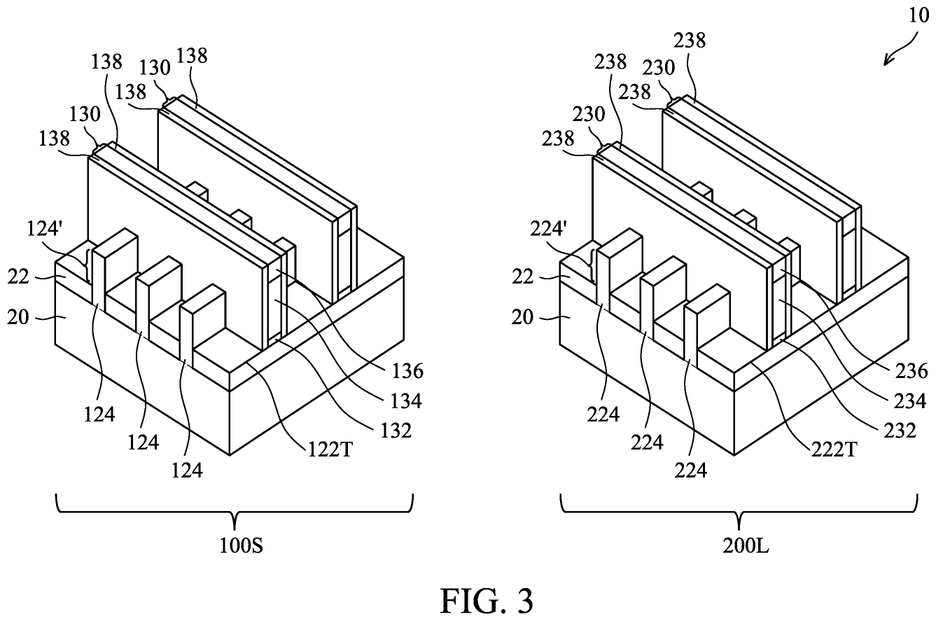

Referring to FIG. 3, dummy gate stacks 130 and 230 are formed on the top surfaces and the sidewalls of protruding fins 124′ and 224′, respectively. The respective process is illustrated as process 404 in the process flow 400 as shown in FIG. 20. Dummy gate stacks 130 may include gate dielectrics 132 and dummy gate electrodes 134 over dummy gate dielectrics 132. Dummy gate stacks 230 may include dummy gate dielectrics 232 and dummy gate electrodes 234 over dummy gate dielectrics 232. Dummy gate electrodes 134 and 234 may be formed, for example, using polysilicon, and other materials may also be used. Each of dummy gate stacks 130 and 230 may also include one (or a plurality of) hard mask layers 136 and 236, respectively. Hard mask layers 136 and 236 may be formed of silicon nitride, silicon carbo-nitride, or the like. Each of dummy gate stacks 130 and 230 crosses over a single one or a plurality of protruding fins 124′ and 224′, respectively. Dummy gate stacks 130 and 230 may also have lengthwise directions perpendicular to the lengthwise directions of the respective protruding fins 124′ and 224′, respectively.

Next, gate spacers 138 and 238 are formed on the sidewalls of dummy gate stacks 130 and 230, respectively. The respective process is illustrated as process 406 in the process flow 400 as shown in FIG. 20. In the meantime, fin spacers (not shown) may also be formed on the sidewalls of protruding fins 124′ and 224′. In accordance with some embodiments, each of gate spacers 138 and 238 includes one or a plurality of dielectric layers formed of different dielectric materials. For example, the dielectric materials may include SiN, silicon oxide, SiON, SiOCN, or the like. The dielectric materials may also include high-k dielectric materials and/or low-k dielectric materials. The formation process of gate spacers 138 and 238 may include blanket deposition processes to form blanket dielectric layers, followed by anisotropic etching processes.

An etching process is then performed to etch the portions of protruding fins 124′ and 224′ that are not covered by dummy gate stacks 130 and 230 and gate spacers 138 and 238, resulting in the structure shown in FIG. 4. The respective process is illustrated as process 408 in the process flow 400 as shown in FIG. 20. The recessing may be anisotropic, and hence the portions of fins 124′ and 224′ directly underlying the respective dummy gate stack 130/230 and gate spacers 138/238 are protected, and are not etched. The top surfaces of the recessed semiconductor strips 124 and 224 may be lower than the top surfaces of the adjacent STI regions 22 in accordance with some embodiments. Recesses 140 and 240 are accordingly formed between STI regions 22. The recessing in device regions 100S and 200L may be performed in a common etching process or in separate processes, and the depths of recesses 140 may be equal to or different from the depths of recesses 240.

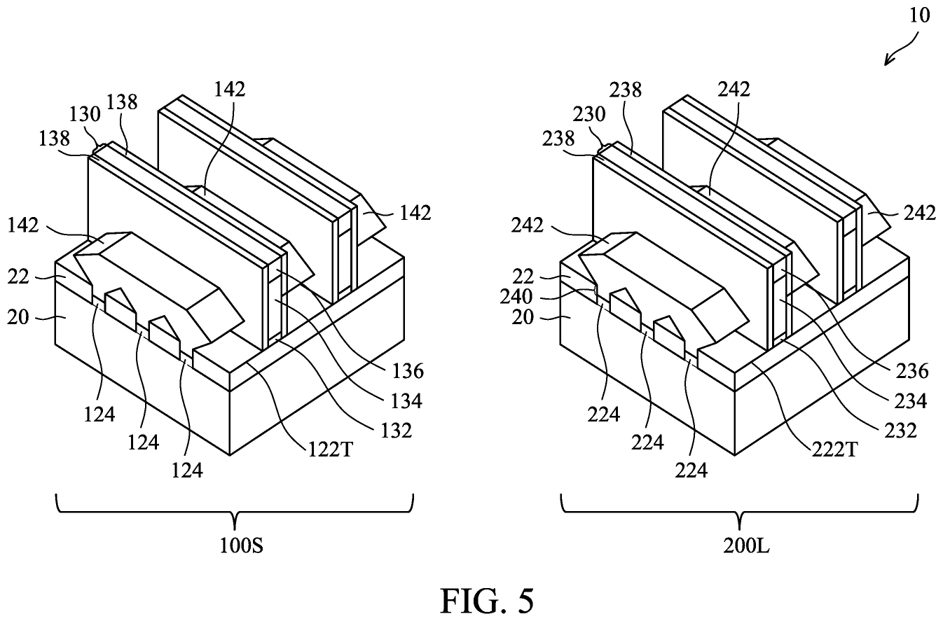

Next, epitaxy regions (source/drain regions) are formed by selectively growing a semiconductor material in recesses 140 and 240 simultaneously (or separately), resulting in the structure in FIG. 5. The respective process is illustrated as process 410 in the process flow 400 as shown in FIG. 20. Each of the FinFETs in device regions 100S and 200L may be an n-type FinFET or a p-type FinFET in any combination. When a FinFET in device region 100S or 200L is an n-type FinFET, the corresponding epitaxy regions 142 or 242 may be formed of or comprise silicon phosphorous (SiP) or silicon carbon phosphorous (SiCP), which is of n-type. Conversely, when a FinFET in device region 100S or 200L is an p-type FinFET, the corresponding epitaxy regions 142 and/or 242 may be formed of or comprise silicon germanium doped with boron (SiGeB), silicon boron (SiB), or the like, which is of p-type. After recesses 140 and 240 are filled with the epitaxy semiconductor material, the further epitaxial growth of epitaxy regions 142 and 242 causes epitaxy regions 142 and 242 to expand horizontally, and facets may be formed. Epitaxy regions 142 and 242 form the source/drain regions of the respective transistors.

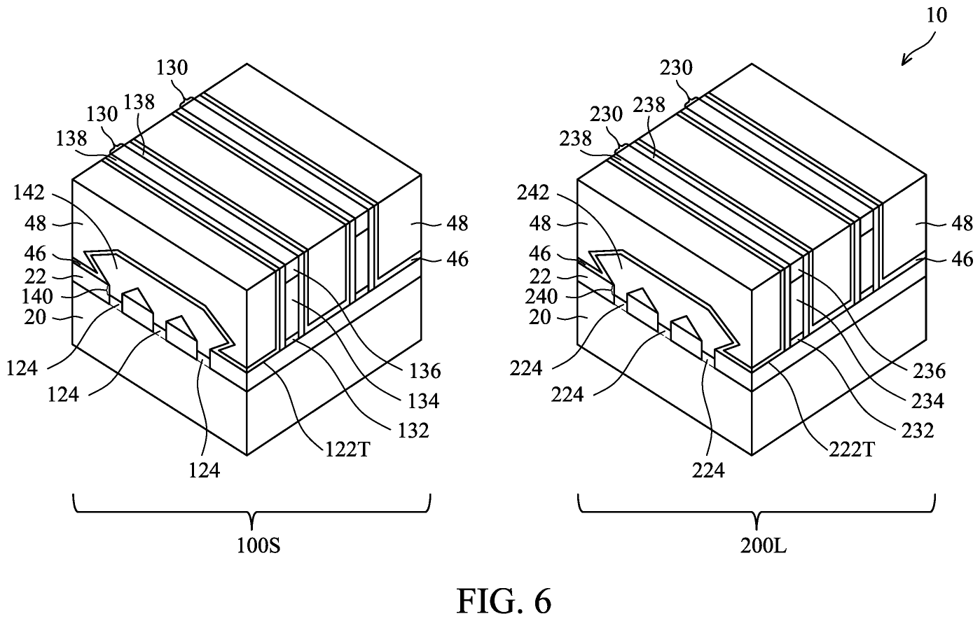

FIG. 6 illustrates a perspective view for forming Contact Etch Stop Layer (CESL) 46 and Inter-Layer Dielectric (ILD) 48. The respective process is illustrated as process 412 in the process flow 400 as shown in FIG. 20. In accordance with some embodiments of the present disclosure, CESL 46 is formed of or comprises silicon nitride, silicon carbo-nitride, or the like. CESL 46 may be formed using a conformal deposition method such as ALD or CVD, for example. ILD 48 is formed over CESL 46, and may be formed using, for example, FCVD, spin-on coating, CVD, or the like. ILD 48 may be formed of silicon oxide, Phospho-Silicate Glass (PSG), Boro-Silicate Glass (BSG), Boron-Doped Phospho-Silicate Glass (BPSG), or the like. A Chemical Mechanical Polish (CMP) process may be performed to level the top surfaces of ILD 48, dummy gate stacks 130 and 230, and gate spacers 138 and 238 with each other.

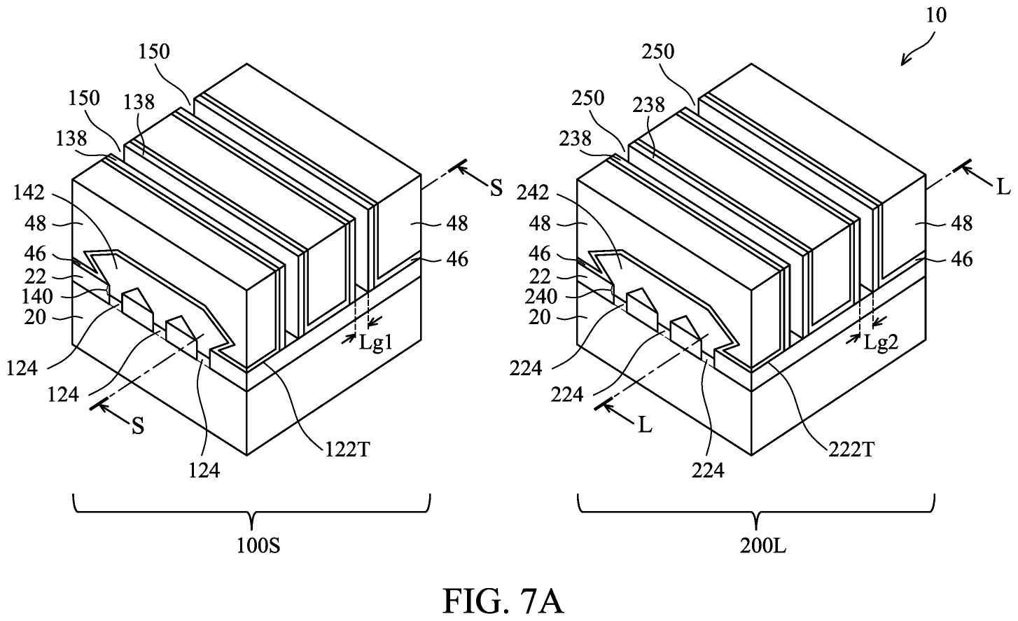

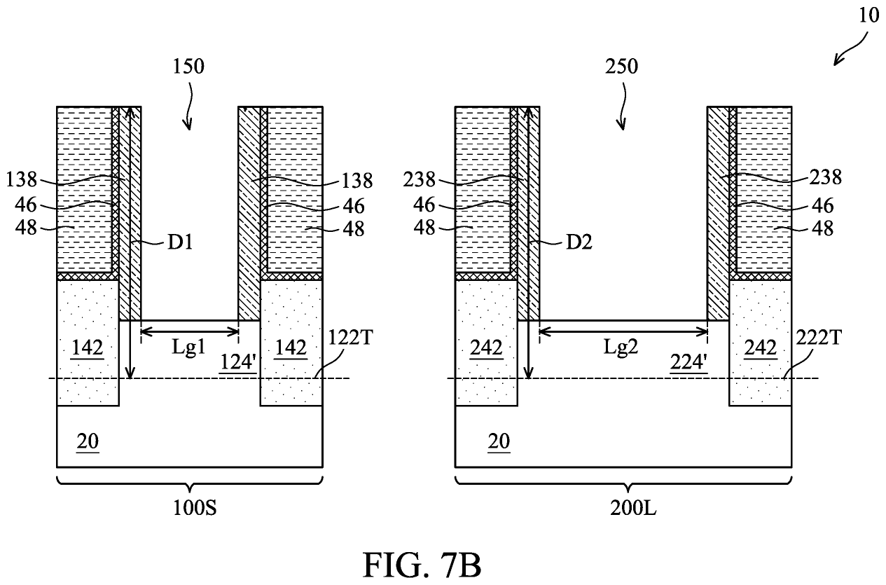

FIGS. 7A and 7B illustrate a perspective view and a cross-sectional view, respectively, after the removal of dummy gate stacks 130 and 230. FIG. 7B illustrates the vertical cross-sections S-S and L-L, which are obtained in device regions 100S and 200L, respectively, in FIG. 7A. Dummy gate stacks 130 and 230 are removed through a plurality of etching processes. Trenches 150 and 250 are thus formed between gate spacers 138 and 238, respectively. The respective process is illustrated as process 414 in the process flow 400 as shown in FIG. 20. Protruding fins 124′ and 224′ are exposed to trenches 150 and 250, respectively.

The channel lengths of the FinFETs in device regions 100S and 200L have values Lg1 and Lg2, respectively. Channel length Lg2 of the long-channel FinFET is greater than the channel Length Lg1 of the short-channel FinFET. The ratio Lg2/Lg1 is greater than 1.0, and may be greater than about 2.5 in accordance with some embodiments. In accordance with some embodiments, the channel-length Lg1 of the short-channel device may be smaller than about 32 nm, and the channel-length Lg2 of the long-channel device may be greater than about 72 nm. In accordance with some embodiments, the short-channel device is a core transistor or a transistor in Static Random Access Memory (SRAM), and the long-channel device is in a transistor in a driver circuit or a peripheral circuit.

Referring to FIG. 7B, the top surfaces of STI regions 22 in device regions 100S and 200L are shown as 122T and 222T, respectively. Trench 150 extends from the top surface of gate spacers 138 to the top surface 122T, with the trench 150 having depth D1. Accordingly, the aspect ratio of trench 150 is D1/Lg1. Trench 250 extends from the top surface of gate spacers 238 to the top surface 222T, with the trench 250 having depth D2. Accordingly, the aspect ratio of trench 250 is D2/Lg2. Since channel length Lg2 is greater than channel length Lg1, aspect ratio D1/Lg1 of trench 150 is greater than aspect ratio D2/Lg2 of trench 150. Depth D1 may be equal to, smaller, or greater than depth D2.

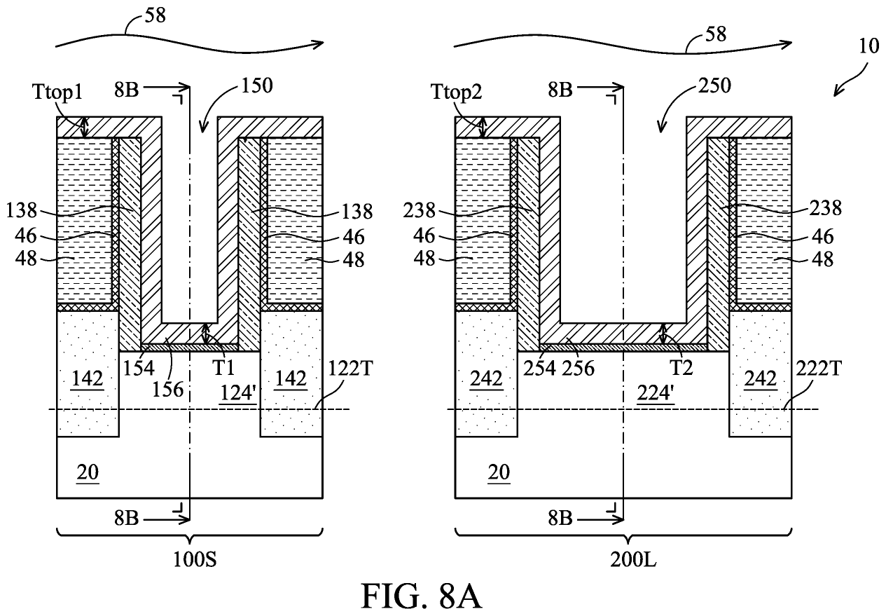

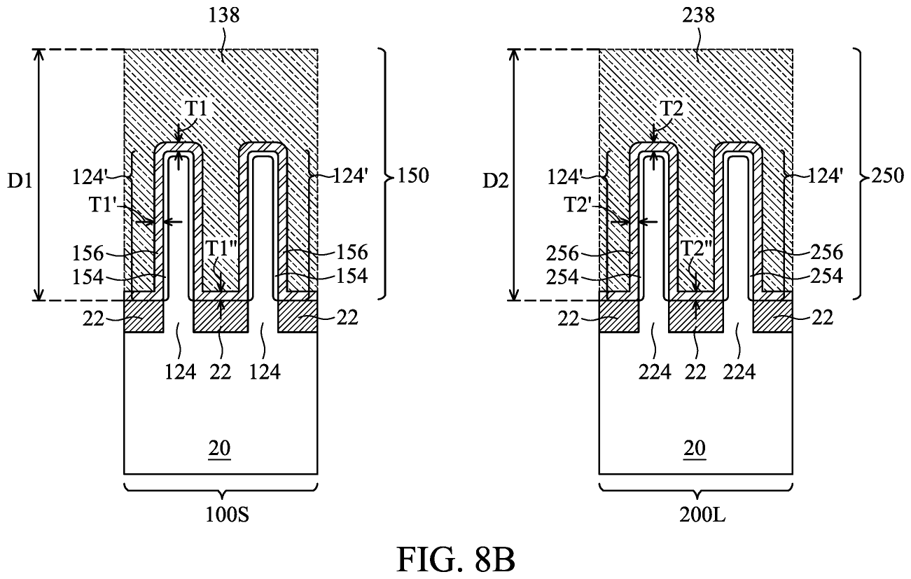

Referring to FIGS. 8A and 8B, Interfacial Layers (ILs) 154 and 254 are formed on the exposed surfaces of protruding fins 124′ and 224′, respectively. The respective process is illustrated as process 416 in the process flow 400 as shown in FIG. 20. FIG. 8B illustrates the cross-sections 8B-8B as shown in FIG. 8A. In FIG. 8B, gate spacers 138 and 238 are shown as being dashed since they are not in the illustrated cross-sections. Gate spacers 138 and 238 are illustrated in FIG. 8B to show where trenches 150 and 250 extend to. Each of ILs 154 and 254 may include an oxide layer such as a silicon oxide layer, which is formed through the thermal oxidation of the surface layers of protruding fins 124′ and 224′, a chemical oxidation process, or a deposition process.

Next, high-k dielectric layers 156 and 256 are deposited on ILs 154 and 254, respectively. High-k dielectric layers 156 and 256 may be deposited in a common deposition process, while different deposition processes may also be used. The respective process is illustrated as process 418 in the process flow 400 as shown in FIG. 20. The deposition may be performed through a conformal deposition process such as an Atomic Layer Deposition (ALD) process, a Chemical Vapor Deposition (CVD) process, or the like. High-k dielectric layers 156 and 256 may be formed of or comprises hafnium oxide, hafnium silicon oxide, lanthanum oxide, aluminum oxide, zirconium oxide, or the like, or combinations thereof. The dielectric constant (k-value) of the high-k dielectric material is higher than 3.9, and may be higher than about 7.0, and sometimes as high as 21.0 or higher. When hafnium oxide is deposited, the precursors may include HF and Tetrakis(ethylmethylamido)hafnium (TEMA). Alternatively, a hafnium-containing precursor such as HfCl₄ may be used in combination with an oxygen-containing precursor such as H₂O, O₂, O₃, or combinations thereof. In accordance with some embodiments in which high-k dielectric layers 156 and 256 are deposited through ALD, a plurality of ALD cycles are performed. In each of the ALD cycles, a hafnium-containing precursor (such as TEMA or HfCl₄) are pulsed into the respective deposition chamber and purged, and then another precursor such as the oxygen-containing precursor or HF is pulsed into the deposition chamber and purged.

Referring again to FIG. 8A, in the deposition process of high-k dielectric layers 156 and 256, the main flow paths of the precursors are above trenches 150 and 250, wherein the main flow paths 58 of the precursors are schematically illustrated. In the deposition of high-k dielectric layers 156 and 256, the precursors diffuse into trenches 150 and 250, and are adsorbed on the exposed surfaces of ILs 154 and 254 and the vertical surfaces of gate spacers 138 and 238 to achieve the deposition. With the increasing down-scaling of the integrated circuit devices, however, the aspect ratios of trenches 150 and 250 become increasingly greater, making the diffusion of the precursors to the bottom parts of trenches 150 and 250 increasingly more difficult.

It is realized that although ALD may be a self-stopping, and ALD has the ability to form a layer having a uniform thickness, the uniform thickness is achieved with the pre-condition of forming uniform precursor layers through adsorption. With the aspect ratios of trenches 150 and 250 being high, however, it is difficult for precursors to reach the bottoms of trenches 150 and 250. Alternatively stated, for a give aspect ratio, precursors may extend to certain depth of the trench with no difficulty. Beyond the certain depth, it is difficult for the precursors to reach. This results in the partial adsorption of precursors at the lower parts of trenches 150 and 250, which means that any given spot of the surfaces of ILs 154 and 254, the adsorption of the spot with a precursor has a probability that is smaller than 100 percent. Furthermore, with the increase in the aspect ratio, the probability of adsorption reduces.

Since trench 150 has a greater aspect ratio than trench 250, in trench 150, the deposition rate of high-k dielectric layer 156 is lower than the deposition rate of high-k dielectric layer 256 in trench 250. Pattern loading effect is incurred. As a result, thickness T1 of high-k dielectric layer 156 is smaller than thickness T2 of high-k dielectric layer 256, wherein thicknesses T1 and T2 are measured at the tops of protruding fins 124′ and 224′, respectively. In an example deposition process, the deposition rate of high-k dielectric layer 256 may be about 0.8 Å/cycle, and the deposition rate of high-k dielectric layer 156 may be about 0.72 Å/cycle. After 20 cycles, the thickness T2 may be 16 A, and thickness T1 may be 15 Å, and the loading is 1 Å. Furthermore, Referring to FIG. 8B, thickness T1′ and T1″ of high-k dielectric layer 156 are smaller than thickness T2′ and T2″, respectively, of high-k dielectric layer 256. Thicknesses T1′ and T2′ are measured at the middle heights of protruding fins 124′ and 224′, respectively, and thicknesses T1'' and T2″ are measured at the bottoms of protruding fins 124′ and 224′, respectively. In addition, as shown in FIG. 8A, thicknesses Ttop1 and Ttop2 may be equal to each other, while thicknesses Ttop1, T1, T1′, and T1″ may be increasingly smaller, and thicknesses Ttop2, T2, T2′, and T2″ may be increasingly smaller.

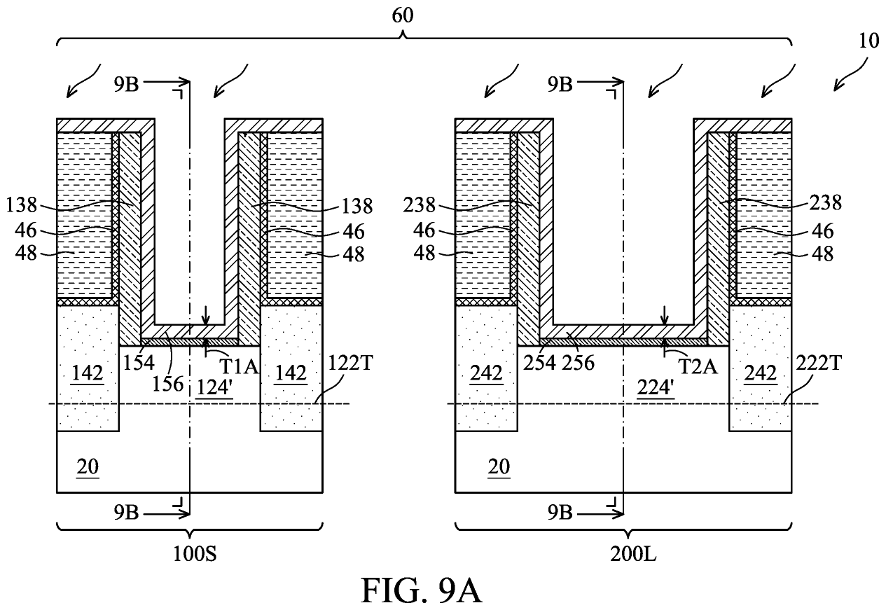

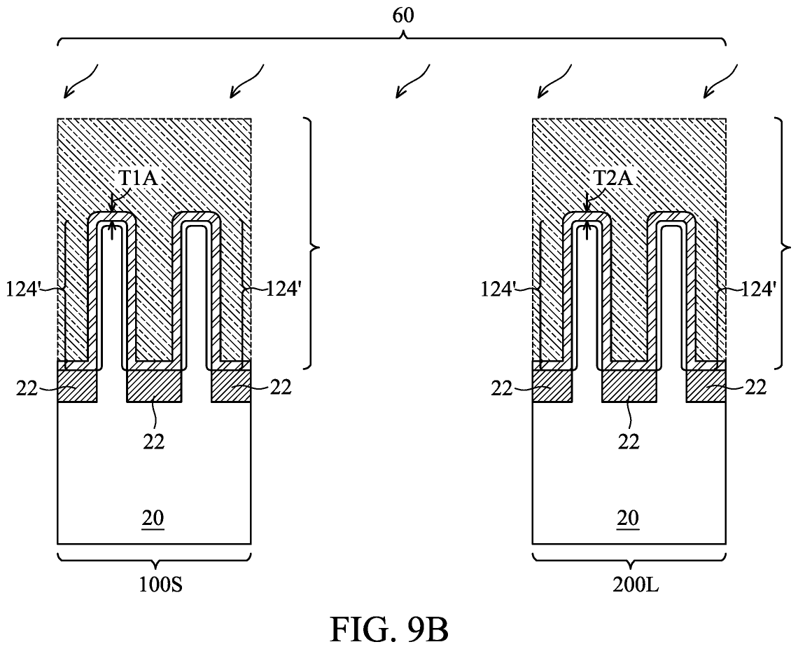

The difference in the thicknesses of high-k dielectric layers 156 and 256 may cause their performance to be different from each other, and may cause the fluctuation in their performance from transistor to transistor. Accordingly, it is desirable that the thicknesses of high-k dielectric layers 156 and 256 to be uniform throughout the respective die. An etch-back process is thus performed to thin high-k dielectric layers 156 and 256, and to bring the thicknesses of high-k dielectric layers 156 and 256 to a same value. The difference between the thicknesses of the high-k dielectric layers of the short-channel FinFET and the long-channel FinFET is thus compensated for. The etch-back process is shown as process 60 in FIGS. 9A and 9B. The respective process is illustrated as process 420 in the process flow 400 as shown in FIG. 20. Due to that the aspect ratio of trench 150 is greater than the aspect ratio of trench 250, loading effect also occurs. The difference between the thickness values T1A and T2A of high-k dielectric layers 156 and 256 is reduced or eliminated. FIG. 9B illustrates the cross-sections 9B-9B as shown in FIG. 9A.

To be able to reduce the difference in the thickness values of high-k dielectric layers 156 and 256, the etching-back process needs to have a greater difference in the etching rates of high-k dielectric layers 156 and 256 than the difference in their deposition rates. For example, assuming the deposition rates of high-k dielectric layers 156 and 256 are DR156 and DR256, respectively, the deposition rate ratio is DR256/DR156. Further assuming the etching rates of high-k dielectric layers 156 and 256 are ER156 and ER256, respectively, the etching rate ratio is ER256/ER156. The Etching rate ratio R256/ER156 needs to be greater than deposition rate ratio DR256/DR156. Otherwise, the etch-back process is unable to result in high-k dielectric layers 156 and 256 to have the same thickness.

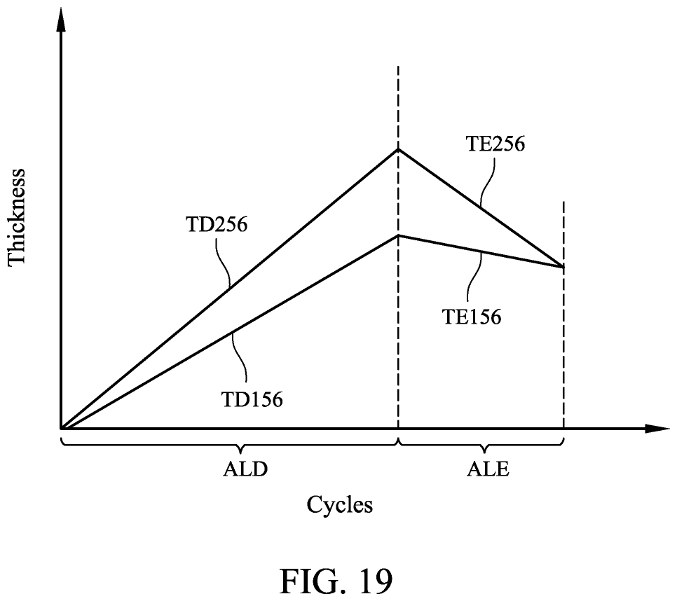

For example, FIG. 19 schematically illustrates the difference in the thicknesses of high-k dielectric layers 156 and 256 as a function of the number of ALD cycles (in their deposition process) and ALE cycles (in their etch-back process). Lines TD156 and TD256 are the thicknesses of high-k dielectric layers 156 and 256 during the deposition process. With the increase in the number of ALD cycles, the difference between the thicknesses of high-k dielectric layers 156 and 256 also increase. Lines TE156 and TE256 are the thicknesses of high-k dielectric layers 156 and 256 during the etching-back process. With the increase in the number of ALE cycles, the difference between the thicknesses of high-k dielectric layers 156 and 256 drops. It is observed that as along as etching rate ratio ER256/ER156 is greater than deposition rate ratio DR256/DR156, the thicknesses of high-k dielectric layers 156 and 256 may reach the same value before their thickness values reach zero. It is also observed that the higher the etching rate ratio ER256/ER156 is, the fewer number of ALE cycles is needed to achieve equal thicknesses.

In accordance with some embodiments of the present disclosure, the increase of the etching rate ratio ER256/ER156 is achieved by selecting proper precursors for the etch-back process, so that the etching rate ratio ER256/ER156 is greater than 1.0, and is at least greater than the deposition rate ratio DR256/DR156.

The increase of the etching rate ratio ER256/ER156 may also be achieved by controlling process conditions such as the temperature of the wafer, the pressure of the precursors, and the like. It is appreciated that the relationship between pressure and adsorption rate (of the etching precursors) is complicated. For example, when the pressure is increased, initially, the adsorption rate increases due to an increase in the number of gas molecules striking on the surface. Thus, an increase in the pressure increases the adsorption rate. With the further increase in the pressure, it will reach a point at which the pressure has no effect on the adsorption rate. Hence, at that point, the extent of adsorption will be independent of the pressure. On the other hand, a lower pressure may result in increased diffusion length into trenches 150 and 250, and hence it is easier for the precursors to reach the bottom of trenches, and the difference in the amount of the precursors reaching the bottoms of trenches is increased. Accordingly, there exists a range of pressure, in which the difference in the adsorption rates of the etching precursor at the bottoms of trenches 150 and 250 is high. Higher or lower than the specific range of pressure, the difference in the adsorption rates (hence the difference in the etching rates) will reduce. In accordance with some embodiments, the pressure of the first and the second precursors during their pulsing stages may be lower than about 30 torr, and may be in the range between about 0.1 torr and about 30 torr.

It is also appreciated that with the rise in temperature, initially, the adsorption rate increases. With further rise in temperature, and above a certain temperature, adsorption starts decreasing. This is because an initial rise in temperature will provide the molecules necessary activation energy for chemical bond formation, and hence the rise of the temperature results in the increase in the adsorption rate. On the other hand, a higher temperature may result in increased diffusion length into trenches 150 and 250, and hence it is easier for the precursors to reach the bottom of trenches, and the difference in the amount of the precursors reaching the bottoms of trenches 150 and 250 is reduced. Accordingly, there exists a range of temperature, in which the difference in the adsorption rates of the etching precursor at the bottoms of trenches 150 and 250 is high. Higher or lower than the specific range of temperature, the difference in the adsorption rates (hence the difference in the etching rates) will reduce. In accordance with some embodiments, the temperature of wafer 10 during the etch-back process may be in the range between about 150° C. and about 450° C.

It is also appreciated that the various factors such as the precursors, the pressure, the temperature, and the like are related to each other, and when one factor is changed, the optimum range of the other factors may change. Accordingly, a plurality of experiments may be performed to form a plurality of sample wafers, on which the structures shown in FIGS. 8A and 8B are formed. The plurality of sample wafers are etched back using different combinations of the factors to determine the optimum factors individually and in combination.

In accordance with some embodiments, the etch-back process is performed through ALE, which may be a plasma ALE process. The precursors may include SF₄ as a first precursor, and TiCl₄ as a second precursor. For example, the SF₄ is first pulsed in the ALE chamber and is then purged. As a result, a fluorination reaction occurs, and the surface layers of high-k dielectric layers 156 and 256 form a fluoride with SF₄. For example, when the etched high-k dielectric layers 156 and 256 include hafnium oxide, hafnium fluoride is generated as a product of the fluorination reaction. The reaction equation may be:

HfO₂₍ₛ₎+2SF_{4(g)}→HfF₄₍ₛ₎+2SOF_{2(g)} [Eq. 1]

In the equation, “S” means solid, and “g” means gas. The TiCl₄ is then pulsed into the ALE chamber and purged. Ligand exchange reaction thus occurs, and the resulting products include HfCl₄ and TiF₄, with both being gases, and may be evacuated from the ALE chamber. The reaction equation may be:

HfF₄₍ₛ₎+TiCl_{4(g)}→HfCl_{4(g)}+TiF_{4(g)} [Eq. 2]

The surface layers of high-k dielectric layers 156 and 256 are thus removed. As aforementioned, high-k dielectric layer 256 is etched faster than dielectric layer 156, resulting in the reduction in the thickness difference. With more ALE cycles being performed, the difference between the thicknesses of high-k dielectric layers 156 and 256 is also reduced to a desirable value, for example, with the high-k dielectric layers 156 and 256 having the same thickness. In an example etch-back process, the etching rate of high-k dielectric layer 256 may be about 0.3 Å/cycle, and the etching rate of high-k dielectric layer 156 may be about 0.1 Å/cycle. After 5 cycles, both of thicknesses T1A and T2A (FIG. 9A) are 14.5 Å, and the loading is eliminated.

It is appreciated that the etching rate ratio ER256/ER156 is related to the material of high-k dielectric layers 156 and 256, and different precursors may be used to suit to different materials. In accordance with alternative embodiments, etching gases such as tetrakis(dimethylamino) (TDMA), Acetylacetonate (ACAC), halide, or the like may be used as the ligand-exchange precursor.

As aforementioned, the etch-back process may compensate for the thickness difference of the high-k dielectric layers of short-channel FinFETs and long-channel FinFETs, so that the thicknesses may be made equal to each other. Due to process variations in the deposition and the etch-back process, however, over-compensation may occur, so that a thickness of the high-k dielectric layers of a short-channel FinFET is greater than a thickness of the high-k dielectric layer of a long-channel FinFET. Accordingly, in a device die, a first thickness of the high-k dielectric layer of a first short-channel FinFET may be greater than a second thickness of the high-k dielectric layer of a first long-channel FinFET, and smaller than a third thickness of the high-k dielectric layer of a second long-channel FinFET.

In accordance with some embodiments, the formation of high-k dielectric layers 156 and 256 includes a single deposition-etching cycle, which includes a deposition process followed by an etch-back process. In accordance with alternative embodiments, the formation of high-k dielectric layers 156 and 256 includes a plurality of deposition-etching cycles, each includes a deposition process followed by an etch-back process.

The deposition process and the etch-back process for forming high-k dielectric layers 156 and 256 may be in-situ performed in a same vacuum environment, for example, in a production tool includes two chambers, with one chamber used for the deposition, and the other chamber used for the etch-back. Between the deposition and the etch-back, there is no vacuum break. In accordance with alternative embodiments, the deposition process and the etch-back process for forming high-k dielectric layers 156 and 256 may be ex-situ performed in different vacuum environments, with vacuum break occurring in between back.

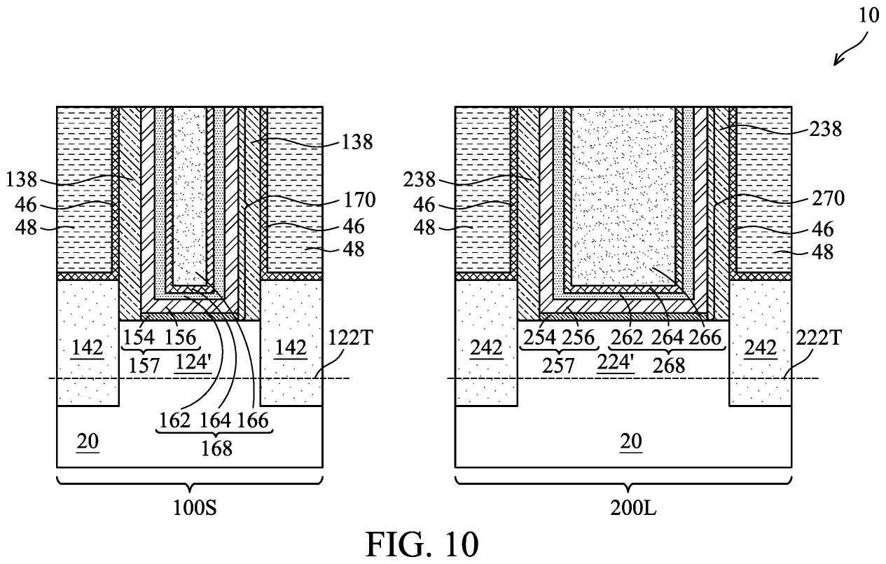

FIG. 10 illustrates the formation of gate electrodes 168 and 268 in accordance with some embodiments. The respective process is illustrated as process 422 in the process flow 400 as shown in FIG. 20. Some or all of the features in gate electrodes 168 and 268 may share common formation processes, or may be formed using different processes. In accordance with some embodiments, gate electrode 168 and 268 may include layers 162 and 262, respectively, which may include a plurality of sub layers therein. The plurality of sub layers are formed through deposition. The deposition may be performed using conformal deposition processes such as ALD and/or CVD processes, so that the horizontal portions and the vertical portions of each of the sub-layers may have thicknesses substantially equal to each other.

Each of layers 162 and 262 may include an adhesion layer and a work-function layer over the adhesion layer. The Adhesion layer may be formed of or comprises Titanium Silicon Nitride (TiSiN) or titanium nitride in accordance with some embodiments. The materials of the work-function layer may include work-function metals selected according to whether the respective FinFETs are n-type FinFETs or p-type FinFETs. For example, when the FinFETs are n-type FinFETs, the corresponding work-function layers may include a plurality of layers formed of different materials therein, which may include a titanium nitride (TiN) layer, a tantalum nitride (TaN) layer, and an Al-based layer (formed of, for example, TiAl, TiAlN, TiA1C, TaA1N, or TaA1C). When the FinFETs are p-type FinFETs, the corresponding work-function layers may include a TiN layer, a TaN layer, and another TiN layer, respectively.

Capping layers 164 and 264, which may be formed of or comprise TiN, may be formed over the corresponding work-function layers. A filling metal (which forms metal regions 166 and 266 after the subsequent planarization) is then filled over capping layers 164 and 264. In accordance with some exemplary embodiments, the filling metal includes W, Cu, Co, Al, Ru, etc. or alloys thereof.

Next, a planarization process such as CMP process or a mechanical grinding process is performed to remove excess portions of the deposited layers over the top surface of ILD 48, and hence replacement gate stacks 170 and 270 are formed. Gate stack 170 includes gate dielectric 157, which includes IL 154 and high-k dielectric layer 156. Gate stack 170 further includes gate electrode 168, which includes stacked layers 162, capping layer 164, and filling metal region 166. Gate stack 270 includes gate dielectric 257, which includes IL 254 and high-k dielectric layer 256. Gate stack 270 further includes gate electrode 268, which includes stacked layers 262, capping layer 264, and filling metal region 266.

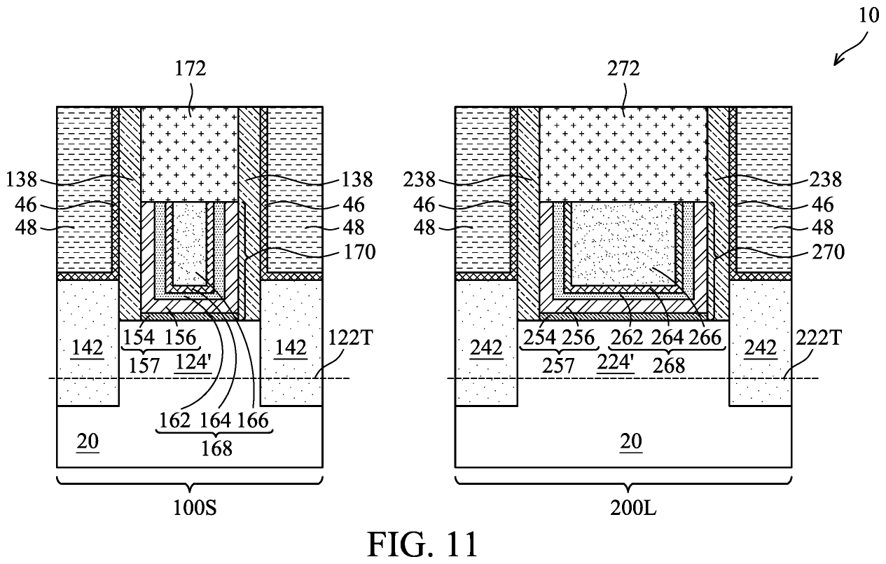

Next, gate stacks 170 and 270 are recessed to form recesses, followed by filling a dielectric material in the recesses, as shown in FIG. 11. Another planarization step is then performed to level the top surfaces of the dielectric material with the top surface of ILD 48, so that hard masks 172 and 272 are formed. Hard masks 172 and 272 may be dielectric hard masks formed of silicon nitride, silicon oxynitride, silicon oxy-carbide, or the like.

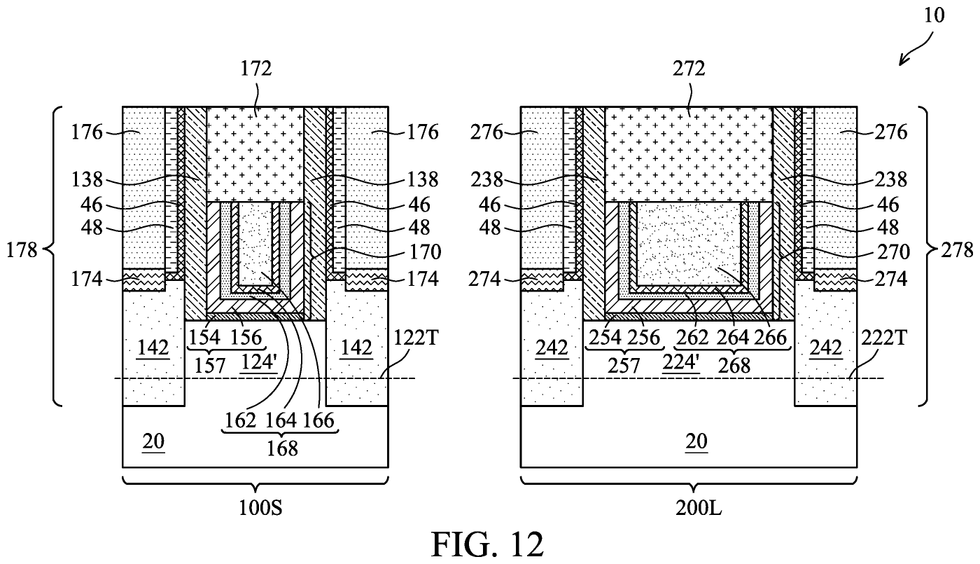

FIG. 12 illustrates the formation of source/drain silicide regions 174 and 274 and source/drain contact plugs 176 and 276. In accordance with some embodiments, contact openings (occupied by contact plugs 176 and 276) are first formed to reveal source/drain regions 142 and 242. A metal layer (a titanium layers for example, not shown) is then deposited as a blanket layer to extend into the source/drain contact openings, followed by a nitridation process performed on the top portion of the metal layer to form metal nitride layers. The bottom portions of the metal layer are not nitridated. Next, an annealing process is performed to react the metal layer with the top portions of source/drain regions 142 and 242 and to form silicide regions 174 and 274. The portions of the metal layer on the sidewalls of ILD 48 are not reacted. Metal regions are then formed to fill the remaining portions of the source/drain contact openings, for example, by filling tungsten, cobalt, or the like. A planarization process is then performed to remove excess materials, resulting in source/drain contact plugs 176 and 276. Short-channel FinFET 178 and long-channel FinFET 278 are thus formed.

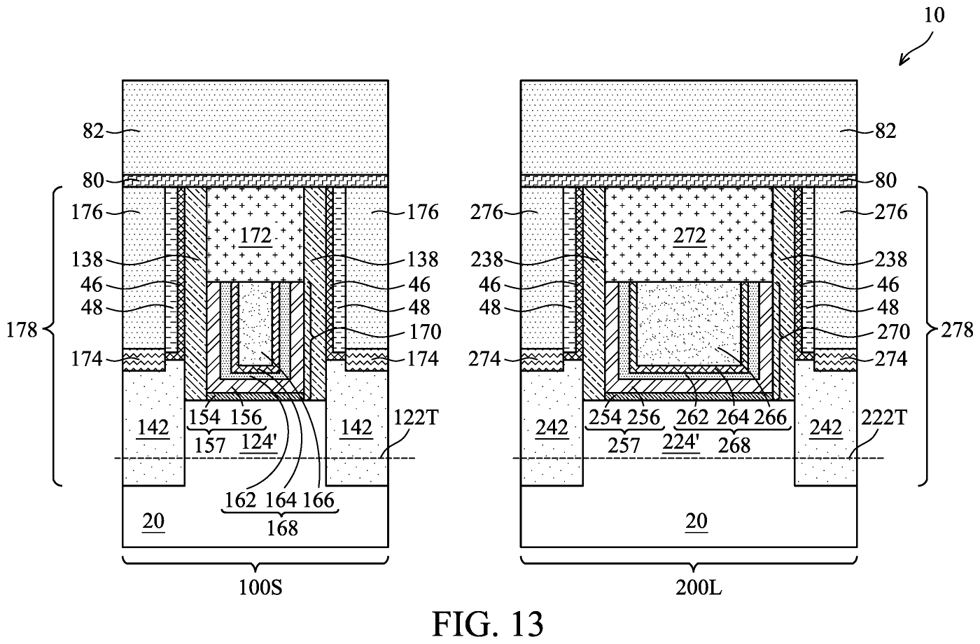

Referring to FIG. 13, etch stop layer 80 is formed. In accordance with some embodiments, etch stop layer 80 is formed of SiN, SiCN, SiC, SiOCN, aluminum oxide, aluminum nitride, combinations thereof, and/or multi-layers thereof. The formation method may include PECVD, ALD, CVD, or the like. Next, ILD 82 is formed over etch stop layer 80. The material of ILD 82 may be selected from the same candidate materials for forming ILD 48, and ILDs 48 and 82 may be formed of the same or different dielectric materials. In accordance with some embodiments, ILD 82 is formed using PECVD, FCVD, spin-on coating, or the like, and may include silicon oxide (SiO₂).

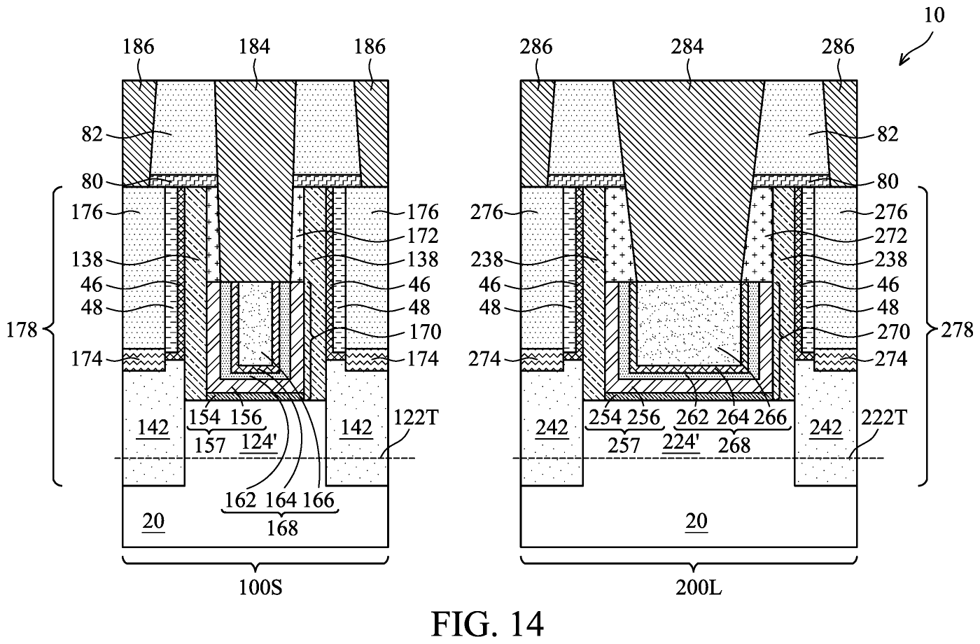

ILD 82 and etch stop layer 80 are etched to form openings (not shown). The etching may be performed using, for example, Reactive Ion Etch (RIE). In a subsequent process, as shown in FIG. 14, plugs/vias 184, 186, 284, and 286 are formed. In accordance with some embodiments of the present disclosure, the formation of plugs/vias 184, 186, 284, and 286 includes forming a blanket barrier layer and a metal-containing material over the blanket barrier layer, and performing a planarization process to remove excess portions of the blanket barrier layer and the metal-containing material.

It is appreciated that although FinFETs are illustrated in preceding embodiments as an example, other types of transistors such as GAA transistors may also adopt the embodiments of the present disclosure. The formation processes of the GAA transistors are similar to the embodiments as presented above, except that the channel regions of the GAA transistors, instead of being formed as fins, may be formed starting from a plurality of silicon layers and SiGe layers stacked alternatingly. The SiGe layers may be removed, so that the remaining silicon layers are suspended. An IL layer and a high-k dielectric layer are formed encircling each of the remaining silicon layers. The high-k dielectric layer may also be formed adopting the embodiments of the present disclosure, and may be formed using a deposition process followed by an etch-back process to reduce the thickness difference between short-channel and long channel GAA transistors. The details for forming the high-k dielectric layer of the GAA transistors may be found in preceding embodiments, and are not repeated herein. The embodiments may also be applied to planar transistors.

In accordance with alternative embodiments, the formation of gate spacers 138 and 238 (FIG. 6) may adopt the embodiments of the present disclosure. For example, in the deposition of the blanket dielectric layer(s), which are etched anisotropically to form gate spacers 138 and 238, since the trenches between gate dummy gate stacks 130 and 230 may have different aspect ratios, the blanket dielectric layers may have different thicknesses. This results in some of the gate spacers to be thicker than necessary, while some other gate spacers may not have enough thickness. Accordingly, in the formation of the blanket dielectric layer(s) for gate spacers 138 and 238, an etch-back process may be performed to reduce the difference between the thicknesses of the portions of the blanket layer(s) for forming gate spacers 138 and 238.

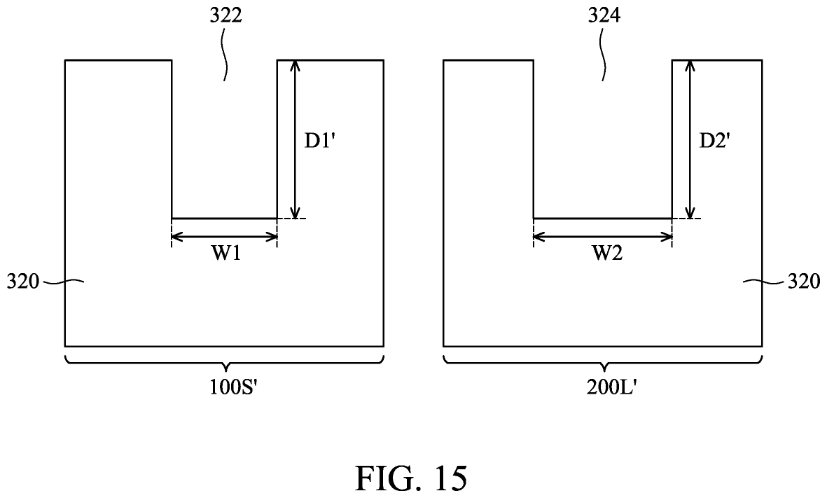

FIGS. 15-18 illustrate the formation of a layer extending into trenches that have different aspect ratios in accordance with some embodiments. Referring to FIG. 15, base structure 320 is provided. Base structure 320 may include a semiconductor substrate, a dielectric substrate, or the like. Furthermore, base structure 320 may have a composite structure including a plurality of regions, layers, materials, and/or the like. For example, base structure 320 may have the structure as shown in FIGS. 7A and 7B. Accordingly, the preceding embodiments are actually an example of the embodiments shown in FIGS. 15-18. Base structure 320 includes a first portion in device region 100S′ and a second portion in device region 200L′, which in the example in the preceding embodiments, correspond to device regions 100S and 200L, respectively.

Trenches 322 and 324 are formed in device regions 100S′ and 200L′ respectively. Trenches 322 and 324 are formed, for example, by etching base structure 320, or by adopting the embodiments as shown in FIGS. 1-6, 7A and 7B. Trench 322 has depth D1′ and width W1. Trench 324 has depth D2′ and width W2. The aspect ratio D1′/W1 may be greater than aspect ratio D2′/W2.

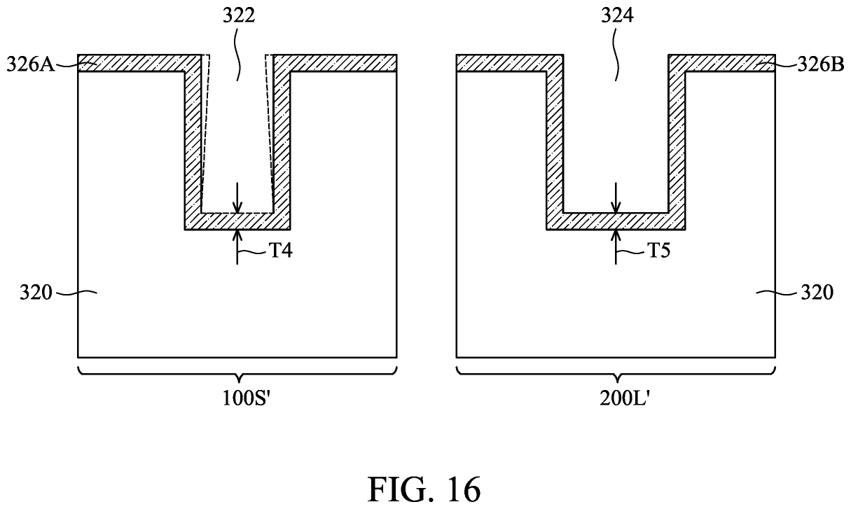

Referring to FIG. 16, layers 326A and 326B are deposited (in a same deposition process or separate deposition processes), and are formed of a same material. In accordance with some embodiments, layers 326A and 326B are dielectric layers, metal layers, semiconductor layers, or the like. For example, layer 326 may be formed of or comprises silicon oxide, hafnium oxide, aluminum oxide, zirconium oxide, or the like. The deposition process may include an ALD process, a CVD process, or the like. The depths and the aspect ratios of trenches 322 and 324 are such that at the bottoms of trenches 322 and 324, the thickness T4 of layer 326A is smaller than the thickness T5 of layer 326B. In accordance with some embodiments, the portions of layers 326A and 326B outside of trenches 322 and 324 are equal to each other. From the top to the bottom of trench 322, the thicknesses of layers 326A and 326B may gradually reduce.

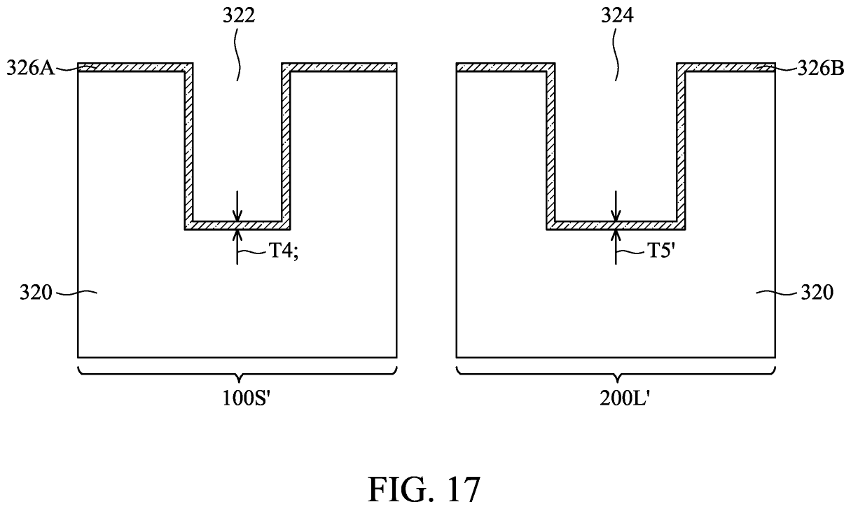

Referring to FIG. 17, an etch-back process is performed to etch back layers 326A and 326B. The etching may be performed by selecting precursors according to the material of layers 326A and 326B, so that a higher loading effect is resulted, and layer 326B is etched faster than layer 326A. The result is that thickness difference (T5′−T4′) is smaller than thickness difference (T5−T4). Thickness T5′ may also be equal to, greater than, or smaller than thickness T4′ in accordance with some embodiments.

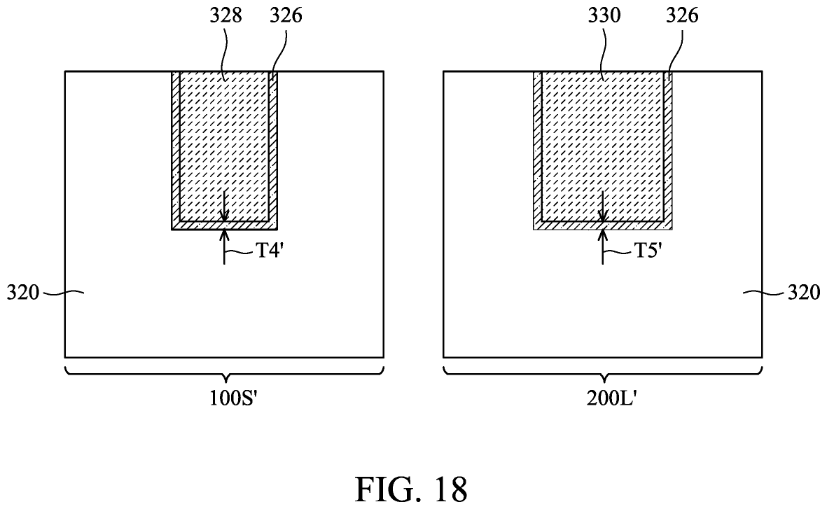

FIG. 18 illustrates the filling of trenches 322 and 324 with filling regions 328 and 330, which may be a dielectric material, a metallic material, a semiconductor material, or the like. A planarization process may be performed to level the top surfaces of filling regions 328 and 330.

The embodiments of the present disclosure have some advantageous features. By performing an etch-back process following the deposition of high-k dielectric layers, the pattern loading effect in the formation of high-k dielectric layers in short-channel transistors and long-channel transistors is compensated for, and the thickness values of the high-k dielectric layers are more uniform.

In accordance with some embodiments of the present disclosure, a method comprises forming a first trench and a second trench in a base structure, wherein the first trench has a first aspect ratio, and the second trench has a second aspect ratio lower than the first aspect ratio; performing a deposition process to deposit a layer comprising a first portion extending into the first trench, wherein the first portion has a first thickness; and a second portion extending into the second trench, wherein the second portion has a second thickness greater than the first thickness by a first difference; and performing an etch-back process to etch the layer, wherein after the etch-back process, the first portion has a third thickness, and the second portion has a fourth thickness, and wherein a second difference between the third thickness and the fourth thickness is smaller than the first difference. In an embodiment, the method further comprises forming additional features over the first portion and the second portion of the layer, wherein at a time the additional features are formed, the fourth thickness is equal to the third thickness. In an embodiment, the etch-back process is performed through an atomic layer etching process. In an embodiment, the layer comprises a high-k dielectric layer, and the etch-back process comprises a fluorination cycle followed by a ligand exchange cycle. In an embodiment, the layer comprises hafnium oxide, and the etch-back process is performed through atomic layer etching using SF₄ and TiCl₄ as process gases. In an embodiment, the method further comprises forming the base structure comprising forming a first dummy gate stack and a second dummy gate stack on a first semiconductor region and a second semiconductor region, respectively; forming first gate spacers and second gate spacers on opposing sides of the first dummy gate stack and the second dummy gate stack; and removing the first dummy gate stack and the second dummy gate stack to form the first trench between the first gate spacers and the second trench between the second gate spacers. In an embodiment, the deposition process is performed through ALD.

In accordance with some embodiments of the present disclosure, a method comprises forming a first dummy gate stack and a second dummy gate stack on a first semiconductor region and a second semiconductor region, respectively; forming first gate spacers and second gate spacers on opposing sides of the first dummy gate stack and the second dummy gate stack; removing the first dummy gate stack and the second dummy gate stack to form a first trench between the first gate spacers and a second trench between the second gate spacers; depositing a first dielectric layer extending into the first trench; depositing a second dielectric layer extending into the second trench; and performing an etch-back process to simultaneously etch-back the first dielectric layer and the second dielectric layer and to reduce a thickness difference between the first dielectric layer and the second dielectric layer. In an embodiment, the first dielectric layer and the second dielectric layer are deposited in a common deposition process. In an embodiment, the first dielectric layer and the second dielectric layer are deposited in an atomic layer deposition process, and wherein a first thickness of the first dielectric layer at a first bottom of the first trench is smaller than a second thickness of the second dielectric layer at a second bottom of the second trench, and after the etch-back process, the first dielectric layer and the second dielectric layer has a substantially same thickness. In an embodiment, the method further comprises, before the depositing the first dielectric layer and the second dielectric layer, forming an interfacial layer on the first semiconductor region and the second semiconductor region. In an embodiment, the depositing the first dielectric layer and the depositing the second dielectric layer comprise depositing high-k dielectric layers. In an embodiment, the depositing the first dielectric layer and the depositing the second dielectric layer comprise depositing a hafnium oxide layer. In an embodiment, the etch-back process is performed through an atomic layer etching process. In an embodiment, the atomic layer etching process comprises a fluorination reaction and a ligand exchange reaction.

In accordance with some embodiments of the present disclosure, a method comprises forming a first dummy gate stack on a first portion of a first protruding semiconductor fin; removing a second portion of the first protruding semiconductor fin to form a recess; forming an epitaxy region from the recess; forming a contact etch stop layer and an inter-layer dielectric on the epitaxy region; removing the first dummy gate stack to form a first trench, wherein the first portion of the first protruding semiconductor fin is exposed; forming an interlayer dielectric on the first portion of the first protruding semiconductor fin; depositing a first high-k dielectric layer extending into the first trench; and performing an etch-back process using atomic layer etching to thin down the first high-k dielectric layer. In an embodiment, the method further comprises forming a second dummy gate stack on a second protruding semiconductor fin; removing the second dummy gate stack to form a second trench, wherein the second protruding semiconductor fin is exposed; and depositing a second high-k dielectric layer extending into the second trench, wherein the etch-back process further thins down the second high-k dielectric layer, and wherein before the etch-back process, the first high-k dielectric layer and the second high-k dielectric layer have a first thickness difference, and after the etch-back process, the first high-k dielectric layer and the second high-k dielectric layer have a second thickness difference smaller than the first thickness difference. In an embodiment, the etch-back process is stopped before the first high-k dielectric layer is fully removed. In an embodiment, the atomic layer etching comprises pulsing and purging SF₄; and pulsing and purging TiCl₄. In an embodiment, the first high-k dielectric layer comprises hafnium oxide.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first trench and a second trench in a base structure, wherein the first trench has a first aspect ratio, and the second trench has a second aspect ratio lower than the first aspect ratio;
performing a deposition process to deposit a layer comprising:
a first portion extending into the first trench, wherein the first portion has a first thickness; and
a second portion extending into the second trench, wherein the second portion has a second thickness greater than the first thickness by a first difference; and
performing an etch-back process to etch the layer, wherein after the etch-back process, the first portion has a third thickness, and the second portion has a fourth thickness, and wherein a second difference between the third thickness and the fourth thickness is smaller than the first difference.

2. The method of claim 1 further comprising forming additional features over the first portion and the second portion of the layer, wherein at a time the additional features are formed, the fourth thickness is equal to the third thickness.

3. The method of claim 1, wherein the etch-back process is performed through an atomic layer etching process.

4. The method of claim 1, wherein the layer comprises a high-k dielectric layer, and the etch-back process comprises a fluorination cycle followed by a ligand exchange cycle.

5. The method of claim 4, wherein the layer comprises hafnium oxide, and the etch-back process is performed through atomic layer etching using SF₄ and TiCl₄ as process gases.

6. The method of claim 1 further comprising forming the base structure comprising:
forming a first dummy gate stack and a second dummy gate stack on a first semiconductor region and a second semiconductor region, respectively;
forming first gate spacers and second gate spacers on opposing sides of the first dummy gate stack and the second dummy gate stack; and
removing the first dummy gate stack and the second dummy gate stack to form the first trench between the first gate spacers and the second trench between the second gate spacers.

7. The method of claim 1, wherein the deposition process is performed through Atomic-Layer Deposition (ALD).

8. A method comprising:
forming a first dummy gate stack and a second dummy gate stack on a first semiconductor region and a second semiconductor region, respectively;
forming first gate spacers and second gate spacers on opposing sides of the first dummy gate stack and the second dummy gate stack;
removing the first dummy gate stack and the second dummy gate stack to form a first trench between the first gate spacers and a second trench between the second gate spacers;
depositing a first dielectric layer extending into the first trench;
depositing a second dielectric layer extending into the second trench; and
performing an etch-back process to simultaneously etch-back the first dielectric layer and the second dielectric layer and to reduce a thickness difference between the first dielectric layer and the second dielectric layer.

9. The method of claim 8, wherein the first dielectric layer and the second dielectric layer are deposited in a common deposition process.

10. The method of claim 9, wherein the first dielectric layer and the second dielectric layer are deposited in an atomic layer deposition process, and wherein a first thickness of the first dielectric layer at a first bottom of the first trench is smaller than a second thickness of the second dielectric layer at a second bottom of the second trench, and after the etch-back process, the first dielectric layer and the second dielectric layer has a substantially same thickness.

11. The method of claim 8 further comprising, before the depositing the first dielectric layer and the second dielectric layer, forming an interfacial layer on the first semiconductor region and the second semiconductor region.

12. The method of claim 8, wherein the depositing the first dielectric layer and the depositing the second dielectric layer comprise depositing high-k dielectric layers.

13. The method of claim 12, wherein the depositing the first dielectric layer and the depositing the second dielectric layer comprise depositing a hafnium oxide layer.

14. The method of claim 13, wherein the etch-back process is performed through an atomic layer etching process.

15. The method of claim 14, wherein the atomic layer etching process comprises a fluorination reaction and a ligand exchange reaction.

16. A method comprising:
forming a first dummy gate stack on a first portion of a first protruding semiconductor fin;
removing a second portion of the first protruding semiconductor fin to form a recess;
forming an epitaxy region from the recess;
forming a contact etch stop layer and an inter-layer dielectric on the epitaxy region;
removing the first dummy gate stack to form a first trench, wherein the first portion of the first protruding semiconductor fin is exposed;
forming an interlayer dielectric on the first portion of the first protruding semiconductor fin;
depositing a first high-k dielectric layer extending into the first trench; and
performing an etch-back process using atomic layer etching to thin down the first high-k dielectric layer.

17. The method of claim 16 further comprising:
forming a second dummy gate stack on a second protruding semiconductor fin;
removing the second dummy gate stack to form a second trench, wherein the second protruding semiconductor fin is exposed; and
depositing a second high-k dielectric layer extending into the second trench, wherein the etch-back process further thins down the second high-k dielectric layer, and wherein before the etch-back process, the first high-k dielectric layer and the second high-k dielectric layer have a first thickness difference, and after the etch-back process, the first high-k dielectric layer and the second high-k dielectric layer have a second thickness difference smaller than the first thickness difference.

18. The method of claim 16, wherein the etch-back process is stopped before the first high-k dielectric layer is fully removed.

19. The method of claim 16, wherein the atomic layer etching comprises:
pulsing and purging SF₄; and
pulsing and purging TiCl₄.

20. The method of claim 19, wherein the first high-k dielectric layer comprises hafnium oxide.
